(19) United States
(12) Patent Application Publication
(10) Pub. No.: US 2026/0310482 A1
(43) Pub. Date: Oct. 8, 2026

(54) METHOD AND DEVICE FOR DIGITAL TWINS

(71) Applicant: Robert Bosch GmbH, Stuttgart (DE)

(72) Inventors: Andreas Mueller, Leonberg (DE); Emine Guenduez, Muenchen (DE); Florian Michel, Rosenheim (DE); Henrik Klessig, Renningen (DE)

(21) Appl. No.: 19/555,514

(22) Filed: Mar. 3, 2026

(30) Foreign Application Priority Data
Mar. 11, 2025 (DE) 10 2025 109 136.6

(51) Int. Cl. G06F 9/455; G06F 9/50

(52) U.S. Cl. CPC G06F 9/45558; G06F 9/5027; G06F 2009/45579

(57) ABSTRACT

A computer-implemented method for digital twins. The method including: managing data associated with at least one digital twin, providing one or more functions for the digital twins, for example for operation of the digital twins, and providing a wireless communication interface for a data exchange between at least one of the following elements: a) a digital twin, or b) a product associated with at least one digital twin, or c) at least one of the functions for the digital twins.

### FIELD

The present disclosure relates to a method for digital twins.

The present disclosure further relates to a device for digital twins.

### SUMMARY

Some examples relate to a method, for example a computer-implemented method, for digital twins, for example for processing data associated with digital twins, comprising: managing data associated with at least one digital twin, providing one or more functions for the digital twins, for example for operation of the digital twins, and providing a wireless communication interface for a data exchange between at least one of the following elements: a) a digital twin, or b) a product associated with at least one digital twin, or c) at least one of the functions for the digital twins. In some examples, this allows, e.g., a platform for digital twins to be provided which allows, e.g., efficient processing of data of a plurality of digital twins that are, for example, at least temporarily related to one another.

In some examples, a digital twin can be regarded as a digital representation of a physical product, such as, e.g., an appliance. Here, e.g., one or more attributes of the digital twin are updated, e.g., in real time, in accordance with the changes in the same attributes of the physical produced item.

In some examples, at least one aspect of the method according to the disclosure can be performed by at least one device, wherein, for example, the at least one device can be a server, for example an edge server or a cloud server. In some examples, a plurality of devices can also be provided for performing at least one aspect of the method according to the disclosure, for example a plurality of servers that can form, e.g., part of a cloud system. In some examples, providing the wireless communication interface comprises using a mobile communication system, for example a cellular mobile communication system, for example of the 6G type or based on 6G.

In some examples, the managing step comprises: executing the at least one digital twin or at least one aspect of the at least one digital twin, for example by means of the device mentioned above as an example or at least one of said devices.

In some examples, the digital twins comprise at least one of the following elements: a) a digital twin of a product, for example an appliance, for example a household appliance, or b) a digital twin of a person, for example a user of a/the product, for example a household appliance.

For example, providing the one or more functions comprises: providing a function for recognizing and/or identifying objects located in spatial proximity relative to one another, for example based on at least one of a) a sensing function, for example of a/the mobile communication system, or b) a positioning function, for example of a/the mobile communication system.

For example, providing the one or more functions comprises: providing a function for protecting at least one aspect, for example an authenticity and/or integrity, of the digital twins and/or of communication of the digital twins, for example via the wireless communication interface.

For example, providing the one or more functions comprises: providing a function for resource management for the digital twins, for example for managing compute resources, for example for identification and/or localization and/or assignment of compute resources to one or more instances of the digital twins. For example, providing the one or more functions comprises: providing a function for enabling, for example providing and/or managing, communication relationships between the digital twins.

For example, providing the one or more functions comprises: providing a function for artificial intelligence, for example machine learning, for example for supporting data processing associated with the digital twins and/or for supporting an interaction of the digital twins.

For example, providing the one or more functions comprises: providing a function for management of a lifecycle, for example lifecycle management, for the digital twins, for example for at least one of a) instantiation, or b) configuration, or c) deactivation of the digital twins.

In some examples, the method comprises: using at least one function of a/the mobile communication system, for example for providing, for example executing, the one or more functions.

In some examples, the method comprises at least one of the following elements: a) establishing data connections to physical products, for example appliances, for example comprising registering and/or connecting the physical appliances with respect to the mobile communication system, for example a 6G mobile communication system, or b) ascertaining a position of at least one appliance and/or ascertaining a digital twin associated with the at least one appliance and/or instantiating a digital twin for the at least one appliance, or c) authenticating at least one digital twin, for example a/the digital twin associated with the appliance, or d) setting up, for example configuring, communication relationships between the digital twins, or e) executing at least one digital twin, for example a/the digital twin associated with the appliance, or f) deactivating communication relationships, for example the communication relationships, between the digital twins.

Some examples relate to a device for digital twins, for example for processing data associated with digital twins, wherein the device is designed, for example configured, to perform the method according to the disclosure.

Some examples relate to a system comprising at least one device according to the disclosure and at least one product for operation with at least one digital twin.

Some examples relate to a product for operation with at least one digital twin, which is, for example, designed to use the wireless communication interface for a data exchange with the at least one digital twin and/or for a data exchange with at least one of the functions for the digital twins.

Some examples relate to a computer-readable storage medium comprising commands that, when executed by a computer, cause said computer to perform the method according to the disclosure. Some examples relate to a computer program comprising commands that, when the program is executed by a computer, cause said computer to perform the method according to the disclosure.

Some examples relate to a data carrier signal that transmits and/or characterizes the computer program according to the disclosure.

Some examples relate to the use of the method according to the disclosure and/or of the device according to the disclosure and/or of the system according to the disclosure and/or of the computer-readable storage medium according to the disclosure and/or of the computer program according to the disclosure and/or of the data carrier signal according to the disclosure for at least one of the following elements: a) providing a system, for example a platform, for an exchange of information of a plurality of digital twins, or b) increasing an efficiency of operation of products, for example appliances, for example household appliances, or c) automating operational sequences of a plurality of products, or d) increasing interoperability of products, for example appliances, for example household appliances, or e) nutrition monitoring, for example for personal and/or medical purposes, or f) optimizing energy management of household appliances, for example lowering energy consumption.

Further features, possible applications and advantages can be found in the following description of examples, which are shown in the figures. All features described or shown form the subject matter of the present disclosure individually or in any combination, regardless of their combination, wording or representation in the description or in the figures.

### BRIEF DESCRIPTION OF THE DRAWINGS

FIG. 1 is a schematic flow chart.

FIG. 2 is a schematic block diagram.

FIG. 3 is a schematic flow chart.

FIG. 4 is a schematic block diagram.

FIG. 5 is a schematic block diagram.

FIG. 6 schematically shows examples of uses.

### DETAILED DESCRIPTION OF EXAMPLE EMBODIMENTS

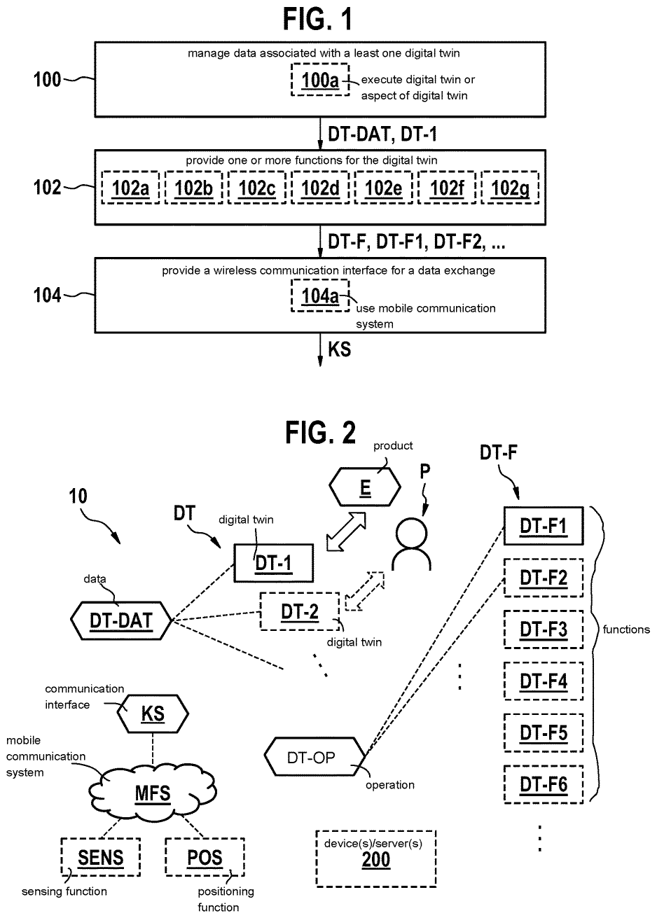

Some examples, see, e.g., FIGS. 1 and 2, relate to a method, for example a computer-implemented method, for (for example one or more) digital twins DT, for example for processing data DT-DAT associated with digital twins DT, comprising: managing 100 data DT-DAT associated with at least one digital twin DT-1, providing 102 one or more functions DT-F, DT-b 1, DT-F2, . . . for the digital twins DT, for example for operation DT-OP of the digital twins DT, and providing 104 a wireless communication interface KS for a data exchange between at least one of the following elements:
a) a digital twin DT, or b) a product E associated with at least one digital twin, or c) at least one of the functions DT-F for the digital twins DT. In some examples, this allows, e.g., a platform or system 10 for digital twins DT to be provided which allows, e.g., efficient processing of data of a plurality of digital twins DT-1, DT-2, ... that are, for example, at least temporarily related to one another.

In some examples, a digital twin DT-1 can be regarded as a digital representation of a physical product E, such as, e.g., an appliance. Here, e.g., one or more attributes of the digital twin DT-1 are updated, e.g., in real time, in accordance with the changes in the same attributes of the physical product E.

In some examples, FIG. 2, at least one aspect of the method according to the disclosure can be performed by at least one device 200, wherein, for example, the at least one device 200 can be a server, for example an edge server or a cloud server.

In some examples, a plurality of devices 200 can also be provided for performing at least one aspect of the method according to the disclosure, for example a plurality of servers that can form, e.g., part of a cloud system or another distributed system. Further details regarding possible designs of the device 200 according to some examples are described further below with reference to FIG. 4.

In some examples, FIG. 1, providing 104 the wireless communication interface KS comprises using 104a a mobile communication system MFS (FIG. 2), for example a cellular mobile communication system, for example of the (3GPP) 6G type or based on 6G.

In some examples, FIG. 1, the managing step 100 comprises: executing 100a the at least one digital twin DT-1 or at least one aspect of the at least one digital twin DT-1, for example by means of the device 200 (FIG. 2) mentioned above as an example or at least one of said devices 200.

In some examples, FIG. 2, the digital twins DT comprise at least one of the following elements: a) a digital twin of a product E, for example an appliance, for example a household appliance, or b) a digital twin of a person P, for example a user of a/the product, for example a household appliance.

For example, FIG. 1, providing 102 the one or more functions DT-F comprises: providing 102a a function DT-F1 for recognizing and/or identifying objects, for example products, located in spatial proximity relative to one another, for example based on at least one of a) a sensing function SENS (FIG. 2), for example of a/the mobile communication system MFS, or b) a positioning function POS, for example of a/the mobile communication system MFS.

For example, providing 102 the one or more functions comprises: providing 102b a function DT-F2 for protecting at least one aspect, for example an authenticity and/or integrity, of the digital twins DT and/or of communication of the digital twins DT, for example via the wireless communication interface KS.

For example, providing 102 the one or more functions comprises: providing 102c a function DT-F3 for resource management for the digital twins DT, for example for managing compute resources, for example for identification and/or localization and/or assignment of compute resources to one or more instances of the digital twins DT.

For example, providing 102 the one or more functions comprises: providing 102d a function DT-F4 for enabling, for example providing and/or managing, communication relationships between the digital twins DT.

For example, providing 102 the one or more functions comprises: providing 102e a function DT-F5 for artificial intelligence (“AI”), for example machine learning (“ML”) , for example for supporting data processing associated with the digital twins DT and/or for supporting an interaction of the digital twins DT.

For example, providing 102 the one or more functions comprises: providing 102f a function DT-F6 for management of a lifecycle, for example lifecycle management, for the digital twins DT, for example for at least one of a) instantiation, or b) configuration, or c) deactivation of the digital twins DT.

In some examples, FIG. 2, the method comprises: using 102g at least one function of a/the mobile communication system MFS, for example for providing 102, for example executing, the one or more functions DT-F.

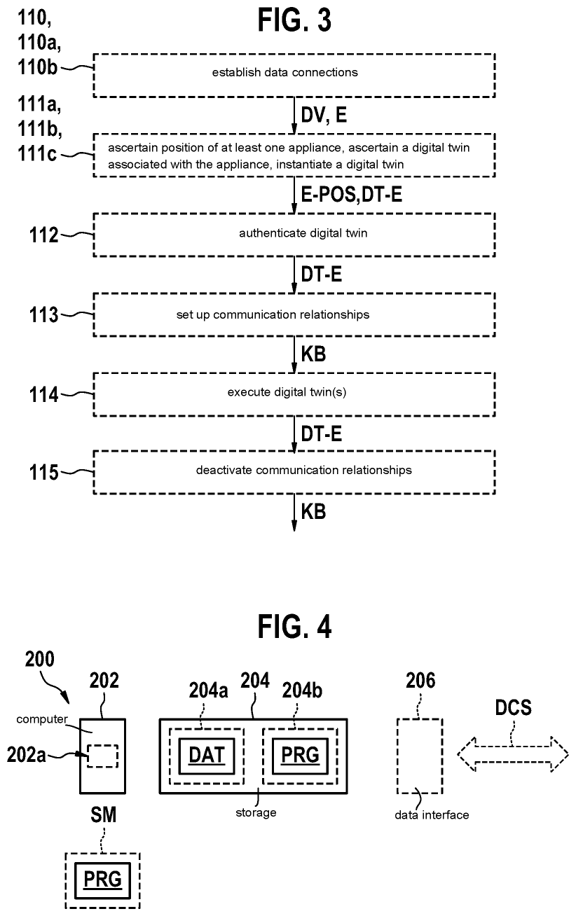

In some examples, FIG. 3, the method comprises at least one of the following elements: a) establishing 110 data connections DV to physical products, for example appliances, E (FIG. 2), for example comprising registering 110a and/or connecting 110b the physical appliances with respect to the mobile communication system MFS, for example a 6G mobile communication system, or b) ascertaining 111a a position E-POS of at least one appliance E and/or ascertaining 111b a digital twin DT-E associated with the at least one appliance and/or instantiating 111c a digital twin DT-E for the at least one appliance E, or c) authenticating 112 at least one digital twin DT-E, for example a/the digital twin associated with the appliance, or d) setting up 113, for example configuring, communication relationships KB between the digital twins DT, DT-E, or e) executing 114 at least one digital twin, for example a/the digital twin DT-E associated with the appliance, or f) deactivating 115 communication relationships KB, for example the communication relationships, between the digital twins DT, DT-E.

Some examples, FIG. 4, relate to a device 200 for digital twins DT (FIG. 2), for example for processing data DT-DAT (FIG. 2) associated with digital twins DT, wherein the device 200 is designed, for example configured, to perform the method according to the disclosure.

In some examples, FIG. 4, the device 200 comprises: a computing apparatus (“computer”) 202 comprising at least one computing core 202a, a storage apparatus 204, assigned to the computing apparatus 202, for at least temporarily storing at least one of the following elements: a) data DAT (e.g., data associated with the digital twins DT and/or the functions DT-F), b) a computer program PRG, for example for performing the method according to the disclosure.

In further examples, FIG. 4, the storage apparatus 204 comprises a volatile memory (e.g., a working memory (RAM) ) 204a, and/or a non-volatile (NVM) memory (e.g., flash EEPROM) 204b, or a combination thereof or with other memory types not explicitly mentioned.

Further examples, FIG. 4, relate to a computer-readable storage medium SM comprising commands PRG that, when executed by a computer 202, cause said computer to perform the method according to the disclosure.

Further examples, FIG. 4, relate to a computer program PRG comprising commands that, when the program PRG is executed by a computer 202, cause said computer to perform the method according to the disclosure.

Further examples, FIG. 4, relate to a data carrier signal DCS that characterizes and/or transmits the computer program PRG according to the disclosure. The data carrier signal DCS is, for example, transmittable (e.g., sendable and/or receivable) via an optional data interface 206 of the device 200. In further exemplary embodiments, the optional data interface 206 uses, e.g., the mobile communication system MFS (FIG. 2).

Some examples, FIG. 2, relate to a system 10 comprising at least one device 200 according to the disclosure and at least one product E for operation with at least one digital twin DT-1.

Some examples, FIG. 2, relate to a product E for operation with at least one digital twin DT-1, which is, for example, designed to use the wireless communication interface KS for a data exchange with the at least one digital twin DT-1 and/or for a data exchange with at least one of the functions DT-F for the digital twins. In some examples, the product E according to the disclosure can also be referred to as an “intelligent product,” since it can allow, e.g., an interaction with other products or their digital twins via its digital twin DT-E.

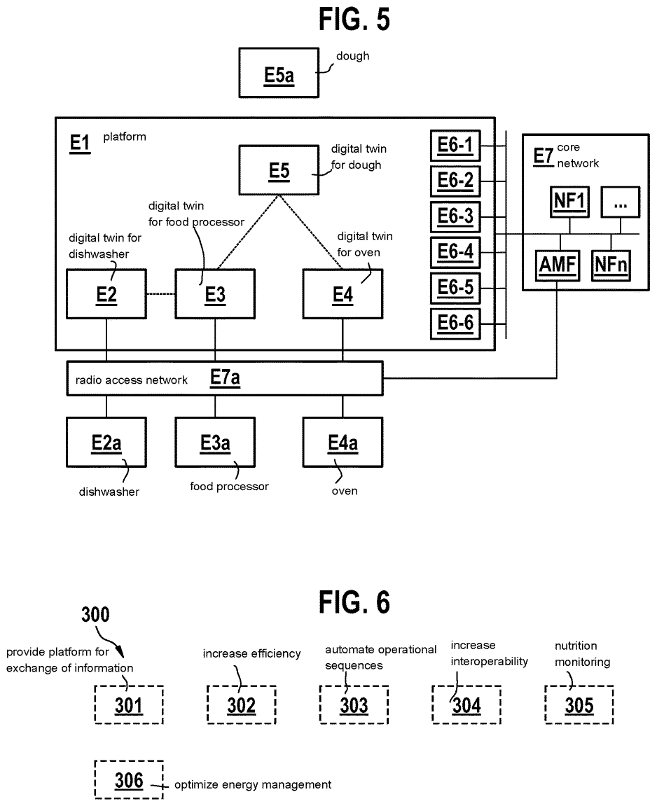

FIG. 5 is a simplified block diagram of aspects according to the disclosure. Depicted is a scenario on the basis of which further examples of the principle according to the disclosure are explained below. Element El symbolizes a platform, e.g., based on a 6G mobile communication system or 6G network, for digital twins E2, E3, E4, E5, as can be provided in some examples, e.g., by means of the system 10 according to FIG. 2.

Element E2 symbolizes a digital twin for a dishwasher E2a.

Element E3 symbolizes a digital twin for a food processor E3a.

Element E4 symbolizes a digital twin for an oven E4a. Element E5 symbolizes a digital twin for a dough E5a. The elements E6-1, E6-2, E6-3, E6-4, E6-5, E6-5 symbolize functions for the platform El or for its digital twins E2, E3, E4, E5, wherein the functions E6-1, E6-2, ... comprise, for example, at least one of the functions DT-F according to FIG. 2.

Element E7 from FIG. 5 symbolizes a core network of a mobile communication system, for example a cellular mobile communication system, and element E7a symbolizes a radio access network (RAN) for the core network E7. The core network E7 can comprise one or more network functions NF1, ..., NFn, e.g., also an AMF (access and mobility function), that is, a function for managing access and mobility functions.

The configuration according to FIG. 5 can be used in some examples for efficiently automating sequences with respect to the products E2a, E3a, E4a, E5a using the platform El, for example based on use of the communication infrastructure E7, E7a. In particular, in some examples, at least one of the following aspects is also enabled: a) an exchange of information of a plurality of digital twins E2, E3, E4, E5 with one another, or b) increasing an efficiency of operation of the products E2, E3, E4, E5, or c) automating operational sequences of a plurality of products E2, E3, E4, E5, or d) increasing interoperability of the products E2, E3, E4, E5, or e) nutrition monitoring, for example for personal and/or medical purposes, or f) optimizing energy management of household appliances, for example for lowering energy consumption. Further details, aspects, and example scenarios in relation to the example configuration according to FIG. 5 are described further below.

Further aspects and examples are described below, which, in further examples, can each be combined individually or in any combination with one another with at least one of the aspects and/or examples described above.

In some examples, FIG. 2, the principle according to the disclosure allows an interaction, for example based on a 6G mobile communication system, of digital twins DT with associated products E, for example appliances, and/or users P.

For example, appliances such as, e.g., household appliances can be personalized using the principle according to the disclosure, for example beyond a degree of personalization that may already be present in some conventional approaches, e.g., provided by predefined and manually configurable user profiles. For example, user profiles for a plurality of appliances can be managed by the system 10 (FIG. 2) according to the disclosure or associated information can be exchanged between different appliances or their respective digital twins. Furthermore, by means of the system 10, e.g., information regarding a presence of a user P and/or the user's intention to use a specific appliance can also be managed, for example be made available to the appliance.

In other words, the system 10 according to the disclosure can allow interconnection and/or an information exchange between a plurality of appliances, which in some examples can lead to better personalization and/or to better results, for example in cooking procedures. For example, the coordination of a plurality of appliances usable, e.g., for a cooking procedure (e.g., a food processor, a stove, an extractor hood, a grill, a microwave, etc.) can be efficiently realized by means of the system 10 according to the disclosure, as can a configuration, e. g., a central configuration, of at least some of the appliances, wherein, for example, a uniform, for example coherent, protocol for an information exchange with the appliances or between the appliances can be provided or used.

In some examples, the principle according to the disclosure allows a degree of personalized usage of products E, for example appliances, e.g., household appliances, to be increased and, e.g., allows an improved interaction with or between the appliances, for example with fewer or no manual interventions at all. Some of these aspects can be achieved, for example, through the use of the system 10 (FIG. 2) or a corresponding secure platform, e.g., with a standardized protocol for an information exchange between the digital representations of the appliances (e.g., digital twins), e.g., household appliances, and/or with a user and/or with products of or items produced by the appliances that can, e.g., also be consumed by the user. In other words, some examples are aimed at allowing an improved interaction with appliances with fewer manual interventions by using a secure platform, e.g., based on and/or in the form of the system 10, wherein coordinated, for example standardized, protocols for an information exchange between different components of the system and/or a user can be used.

In some examples, FIG. 2, the wireless communication interface KS according to the disclosure can be provided, e.g., by means of a mobile communication system MFS according to or based on the 3GPP standard, e.g., of the 5G or 6G type. As a result, in some examples, it is possible to use, for the wireless communication interface KS, a communication performance that is improved, e.g., compared to earlier mobile communication standards. Likewise, functions newly provided, e.g., with the 6G standard can be used for the method and system 10 according to the disclosure. In some examples, it is possible that, by means of the mobile communication system MFS, e.g., of the 6G type, connectivity will be available, e.g., even within structures such as, e.g., buildings, e.g., apartments, so that corresponding functions of the mobile communication system MFS according to the disclosure can, e.g., also be made available to end users, e.g., in a private, e.g., indoor, environment, e.g., for providing intelligent kitchens and/or living spaces.

In some examples, FIG. 2, e.g., a sensing function, for example according to the principle of integrated sensing and communication, e.g., integrated sensing and communication, ISAC, of the mobile communication system MFS, e.g., of the 6G type, can £ be used for aspects according to the disclosure, such as, e.g., the system 10 and/or the method according to the disclosure. That is, in some examples, the mobile communication system MFS is used, e.g., not solely for wireless communication, but can, e.g., at least temporarily also be used for sensing, e.g., with respect to components of the system 10 according to the disclosure.

“Sensing” in the context of 3GPP ISAC refers, e.g., to the capability of a communication system to detect environmental information by analyzing signals. This technology uses, e.g., a communication infrastructure of the mobile communication system MFS (FIG. 2) in order, in addition to wireless data transmission, also to fulfill sensor-related functions, such as, e. g., recognizing objects, and/or determining their position and/or speed, along with analyzing environmental conditions. In some examples, ISAC or the sensing can, e.g., also be used at least temporarily for at least one component of the system 10, e.g., for products or their digital twins, e.g., for recognizing other products in an environment of a first product, etc.

For example, it is to be expected that future mobile communication systems of or based on the 6G type will use comparatively high-frequency bands (e.g., a frequency range “FR2” between about 24 GHZ and about 71 GHZ) and/or comparatively large bandwidths and/or a comparatively dense distribution of antenna arrays, e.g., in order to implement or improve ISAC functions. This can thus improve both wireless communication and detection of physical environmental parameters. Therefore, these aspects can also be used in some examples for aspects according to the disclosure. For example, end appliances (user equipment) or data modems for such mobile communication systems MFS, e.g., of the 6G type or based on the 6G type, can be integrated into at least some products E (FIG. 2), as a result of which, e.g., aspects of the wireless communication interface KS according to the disclosure can be flexibly provided that, e.g., simultaneously also provide sensing or ISAC functionality. In some examples, products E provided with 6G communication or sensing functionality can, for example, be referred to as “intelligent products.” In some examples, integration, for example an integration process, e.g., of aspects of the mobile communication system MFS and/or of the system 10 according to the disclosure, can take place on different levels, e.g., from loosely coupled systems up to fully integrated systems. One example of an application of a technology according to the disclosure is, e.g., an autonomous vehicle that operates more efficiently in changing weather and lighting conditions without requiring separate and expensive radar and lidar appliances, because corresponding object or obstacle recognition functions can be provided, e.g., by the ISAC functionality. Moreover, using 6G mobile communication systems, an improved capability for interconnected sensors can be provided, which is also usable in some examples, for example for integrating into the products E (FIG. 2).

In some examples, FIG. 2, thus, using a mobile communication system MFS of the 6G type, a sensing functionality that can be integrated or is integrated, e.g., into the system 10, and/or a 6G-based platform for digital twins that can be integrated or is integrated, e.g., into the system 10 can be provided.

As already described above, in some examples, a digital twin can be regarded as a digital representation of a physical product or object, in which, e.g., the attributes of one side (e.g., the physical product) are updated in accordance with the changes in the same attributes of the other side (e.g., the digital twin).

If, for example, a calculation of an optimum temperature of an oven (see, e.g., element E4a according to FIG. 5) is specified by an intelligent algorithm in a digital twin E4, then, e.g., the temperature of the real physical oven E4a is synchronized accordingly. In some examples, information flows automatically, that is, e.g., without human interaction, between a digital twin DT-1 (FIG. 2) and a physical product E assigned thereto.

In some examples, FIGS. 2 and 5, a plurality of digital twins DT can also interact with one another in a virtual region, e.g., via a direct data exchange with one another, for example using corresponding hardware (e.g., the device 200), and/or via the wireless communication interface KS or the mobile communication system MFS. In some examples, the virtual interactions of the plurality of digital twins with one another described above also take place, e.g., as well with respect to their respectively associated physical products E in reality.

For example, it is also possible to provide more than one hardware platform, e.g., device 200, for the digital twins DT, so that, in some examples, a first number of digital twins is managed, for example executed, on a first hardware platform, and a second number of digital twins is managed, for example executed, e.g., on a second hardware platform, wherein a data connection between the hardware platforms can in turn be realized, for example, via the wireless communication interface KS or the mobile communication system MFS.

In some examples, for at least one of the aspects a) lifecycle management, b) linking and/or jointly configuring a plurality of digital twins DT, functions, for example automation functions, can be provided that can be realized, for example at least partially, by means of the (e.g., 6G) mobile communication system MFS.

For example, FIG. 2, using the principle according to the disclosure, a system 10, for example a platform, for digital twins DT can be provided that realizes one or more aspects of an operating system for digital twins, such as, e.g., a series of supporting functions such as the recognition of digital twins, the lifecycle management of digital twins, geoproximity services, open APIs, billing, authentication, and others. At least some of these aspects can, in some examples, be realized, e.g., by means of at least one of the functions DT-F (FIG. 2).

In some examples, using the principle according to the disclosure, a digital twin platform, that is, a platform for digital twins DT (FIG. 2), can be provided that uses a 6G mobile communication system, for example is based on a 6G mobile communication system, to which, e.g., one or more household appliances and, e.g., at least one mobile appliance of a user P can be connected, for example are connected, wherein the platform or individual aspects thereof can, in further examples, be adapted to specific application cases of the household appliances.

In some examples, due to a combined use of 6G connectivity, 6G sensor functions, and a 6G-based digital twin platform, see, e.g., the system 10 according to FIG. 2, possible application cases for the household appliances can be improved, for example expanded, by an automated information exchange and/or an interaction of the respective digital twins DT of the system 10, as a result of which, in some examples, an efficiency of operation can also be increased and, e.g., energy savings can be achieved.

In some examples, e.g., through an interaction allowed according to the principle of the disclosure, e.g., between the digital twins DT and/or other components of the system 10 (FIG. 2), at least temporarily one or more of the following advantages V1, V2, ... can be achieved:

(V1) Improved adaptation and/or personalization of appliance operation, e.g., due to localization and/or identification of the user (e.g., through 6G localization and recognition functions, e.g., ISAC), for example through proactive activation and adaptation of a user profile, e.g., already before a first physical interaction of the user with the appliance. Thus, e.g., an intelligent oven (see, e.g., element E4a according to FIG. 5) can, for example, make recipe suggestions on the basis of the user's preferences or automatically adapt cooking times, so that optimum results are achieved.

(V2) More efficient and more effective operation of appliances through information exchange, e.g., proactive and adapted preheating of an oven E4a (FIG. 5), e.g., if a food processor E3a has almost completed a produced item such as a dough E5a.

Likewise, automation of processes and the seamless integration of devices allows more efficient performance of household tasks. For example, an intelligent washing machine can automatically select the optimum wash cycle and inform the user when the laundry is finished. (V3) Minimization of manual user interaction and/or configuration, e.g., of user profiles, e.g., preselection and adaptation of the preparation of a cup of coffee by a coffee machine that a user has not yet actually used.

### (v4) Standardized Method for Instantiation And/or Interaction of

the digital twins DT (FIG. 2) within the mobile communication system MFS, for example a 6G system, and thus, e.g., improved interoperability between different appliances and reduced manual configuration effort.

(V5) The possibility of generating new digital twins from the existing ones, which are representations of the items produced by the appliances, e.g., a representation E5 of the dough E5a prepared in the food processor E3a (FIG. 5), including a list of the ingredient quantity and other attributes such as the energy amount for personal nutrition monitoring. In other words, in some examples, for an item, such as the dough mentioned above as an example, that is produced by means of a product E having its own digital twin, a corresponding digital twin can also be created.

(V6) The possibility of transferring such a digital twin of a new produced item (e.g., a dough) from one appliance to another, while the second appliance is configured on the basis of additional information contained in the digital twin of the produced item, e.g., the automatic configuration of an oven (the mode, the temperature, the humidity, the duration, etc.) on the basis of the properties of the dough (the volume, the water content, the presence of certain ingredients, etc.) . (V7) Optimization of a user interface on the basis of user settings or impairments. (V8) Improved communication performance between applications through more reliable 6G connectivity, e.g., instead of other connectivity solutions that may be less powerful or may offer fewer functions.

(V9) Increased user comfort, user-friendliness, user experience, and generally better results when using the appliances. With the aid of personalized usage, the system 10 can be adapted, e.g., to the individual needs and preferences of the users. This allows intuitive usage and increases user-friendliness, and thus also reduces a risk of incorrect usage or dangerous operating states of the appliances, as a result of which safety can be increased. (V10) Through interconnection of household appliances with corresponding appliance pairs (possible examples of appliance pairs are mentioned further below), the household appliances or operation thereof can be optimized. Thus, for example, an “intelligent” coffee machine can automatically select the correct preparation method and time for a certain type of coffee, etc., in order to achieve the best possible taste experience.

(V11) In some examples, the principle according to the disclosure allows intelligent energy management in household appliances. The appliances can optimize, e.g., energy consumption by adapting themselves to the habits and preferences of the user. As a result, energy consumption is lowered and the environmental balance is improved.

Listed below are some examples B1, B2, ... of appliance pairs according to the disclosure: (B1) a smartphone and a coffee machine, (B2) a food processor and an oven, (B3) a stove and an extractor hood, (B4) a washing machine and a dryer, (B5) a living room and a vacuum cleaner, (B6) a garden and a lawn mower, (B7) a lighting system and motion sensors, (B8) a water filter and a faucet.

In further examples, the number of digital twins that interact with one another, for example in the sense of the above-mentioned groups of appliances, is not limited to two.

In some examples, FIG. 2, a system 10 or platform for digital twins DT can provide one or more functionalities in order to support an interaction of the digital twins, e.g., of household appliances. For example, at least one of the functions DT-F described above with reference to FIG. 2 can be used for this purpose.

In some examples, supporting features and/or functions for a platform for digital twins DT in connection with household appliances (which, in further examples, can also be generalized to other use scenarios) comprise at least one of the following elements: a) recognizing and identifying objects in spatial proximity relative to one another (e.g., interaction with a localization and detection function, for example a network function, of the 6G mobile communication system MFS), e.g., through a detection and discovery (DDF) function, see for example the function DT-F2 according to FIG. 2, or b) authentication and integrity protection of digital twins and their communication by a digital twin authentication server function (DTASF), see for example the function DT-F2 according to FIG. 2, or c) compute resource management for digital twins for identifying, localizing, and assigning compute resources to instances of digital twins (DTRMF), see for example the function DT-F3 according to FIG. 2, or d) enabling communication relationships between digital twins through a digital twin routing function (DTRF), see for example the function DT-F4 according to FIG. 2, or e) providing AI/ML functionality for supporting the processing and interaction of digital twins (AISF), see for example the function DT-F5 according to FIG. 2, or f) digital twin lifecycle management function for the instantiation, configuration, and deactivation of digital twins (DTLMF), see for example the function DT-F6 according to FIG. 2. In some examples, these, for example supporting, functions DT-F can at least partially be 3GPP network functions for the mobile communication system MFS, e.g., within a 5G/6G core network service-based architecture, e.g., functions that can either already exist or be new, e.g., for 3GPP, or separate functions (e.g., functions separate from the mobile communication system MFS) that interact, e.g., via, for example clearly, defined interfaces with network functions, for example 3GPP network functions, e.g., application functions (“AF”) .

Alternatively or additionally, in some examples at least some of the functions DT-F (FIG. 2) can at least partially and/or at least temporarily use at least one of the mentioned 3GPP functions, e.g., build thereon.

In some examples, at least one component of the system 10 (FIG. 2) according to the disclosure can interact with at least one of the following existing 3GPP network functions: a) a policy control function (PCF), or b) a session management function (SMF), or c) an authentication server function (AUSF), or d) unified data management (UDM), or e) a location management function (LMF).

In some examples, FIG. 2, an interaction of digital twins DT according to the disclosure can be divided into the following phases P1, P2, . . . : (P1) registering and connecting the physical appliances to a mobile communication system MFS, e.g., based on or represented by a 6G network (involved, e.g.: a 5G/6G core), or (P2) recognizing a location of objects and/or appliances and ascertaining the associated digital twin(s), e.g., if these are already instantiated (involved: e.g., a function DDF (DT-F1)), or newly instantiating the digital twins (involved, e.g.: DTLMF (DT-F6), DTRMF (DT-F3)), or (P3) authenticating the digital twins(s) (involved, e.g.: DTASF (DT-F2)), or (P4) setting up and configuring the communication relationships between the digital twins DT (involved, e.g.: DTRF (DT-F4)), or (P5) the overall system is operationally ready (e.g., involved: a 6G application layer, optionally AISF (DT-F5)), or (P6) a digital twin/digital twins DT indicate completion of the interaction, or (P7) communication relationships of the digital twin and digital twins DT are deactivated (involved, e.g.: DTRMF (DT-F3), DTLMF (DT-F6)). In some examples, there are different possibilities for implementing one or more of the functions DDF or DT-F1, DTASF or DT-F2, DTRMF or DT-F3, DTRF or DT-F4, AISF or DT-F5, DTLMF or DT-F6 mentioned above. Possible examples are standardized software APIs (application programming interfaces), e.g., possibly based on generic APIs along with suitable metadata and/or manifests of the particular digital twin, which, e.g., indicate which functions the digital twin can provide or comprises, and/or how these functions of the digital twin can be accessed), and/or RESTful interfaces.

Further aspects and examples according to the disclosure are described below on the basis of an example scenario comprising a coffee machine and a user. For the present example, it is assumed that a person is approaching a coffee machine, e.g., in order to prepare a coffee. The person is not carrying, e.g., an end appliance (e.g., user equipment, UE) for a mobile communication system MFS. However, the coffee machine is associated, for example, with a 6G network, for example connected thereto, i.e., the 6G network possesses knowledge regarding the existence and, if applicable, the position of the coffee machine. For example, the coffee machine can use a wireless communication interface KS (see also FIG. 2) of the 6G network, e.g., by means of an end appliance for the 6G network that is provided for the coffee machine, for example integrated into the coffee machine. For example, the 6G network recognizes the approaching person, e.g., by means of an ISAC-method, identifies the person, and recognizes the person's intention to approach the coffee machine-for example through advanced sensors and/or AI capabilities (e.g., under the assumption of an already existing sensor and positioning service function, e.g., DDF, AISF; see also the functions DT-F according to FIG. 2). The 6G network then localizes and identifies the digital twin of the coffee machine and the digital twin of the person, which, e.g., contains information, for example attributes, that describe, e.g., the coffee preferences and, if applicable, existing dietary restrictions of the person. Subsequently, the 6G system supports the coupling of the digital twins of the coffee machine and of the person and thus allows a secure data exchange and an interaction of the digital twins, for example using the function DRF or DT-F4. The interaction of the digital twins leads, e.g., to the coffee machine selecting and personalizing a brewing program according to the user's preferences and, if applicable, dietary restrictions and, e.g., to brewing the coffee after a short confirmation by the user (e.g., by a certain gesture that is recognized by the 6G network, e.g., by means of ISAC).

Alternatively or additionally, the display of the coffee machine can automatically be adapted to the user's preferences, e.g., by selection of the correct language, and/or offering a preferred user interface of this user, etc. For example, the user can still make the final decision regarding which coffee the user wants to order via a standard but personalized user interface. As soon as the person drinks the coffee, e.g., the digital twin of the coffee machine again interacts with the digital twin of the person, e.g., in order to update nutrition information, e.g., in relation to energy and/or caffeine intake. Finally, after completion of the interaction, the communication relationships between the digital twins are securely deactivated by the 6G system (e.g., by means of DTRMF or DT-F3, DTLMF or DT-F6).

Further aspects and examples according to the disclosure are described below on the basis of an example scenario comprising a food processor, a dishwasher, an oven, and a cake; see, e.g., also elements E3a, E2a, E4a, E5a according to FIG. 5. As an illustrative example, in the present case it is assumed that a person P (FIG. 2) would like to bake a cake and, for this purpose, selects, in an app (e.g., on a smartphone (not shown) ), a recipe for this cake. The person's appliances, see FIG. 5, i.e., the food processor E3a, a dishwasher E2a, and an oven E4a, are connected to a 6G system E7, E7a that can be used, e.g., for the system 10 described above with reference to FIG. 2. For example, the person starts a “baking procedure” by switching on the food processor E3a (FIG. 5) and placing all required ingredients therein according to the recipe. The food processor E3a recognizes this and uses the DTLMF or the function DT-F6 according to FIG. 2 in order to create a new digital twin E5 that temporally represents the cake E5a or a dough therefor and its state (at this point in time, e.g., a list of the ingredients). The digital twin E5 of the cake or dough E5a can be updated, e.g., repeatedly, for example periodically, for example permanently, wherein, for example, aspects such as the room temperature and humidity (which can be retrieved, e.g., from a digital twin (not shown) of a room in which the cake is located), the time since production of the dough, and other aspects can be taken into consideration. In this manner, the digital twin E5 always reflects the current state of the cake or of the dough, which can change, e.g., through moisture loss, protein coagulation, and similar effects. Since the digital twin E5 of the cake E5a is instantiated, e.g., by another digital twin E3 (e.g., of the food processor E3a), this other digital twin E3 can, e.g., also define communication relationships according to a “baking process” and correspondingly instruct the functions DTRMF or DT-F3 and DTRF or DT-F4. In this case, the digital twin E4 of the oven E4a can interact, e.g., with the digital twin E5 of the cake E5a and the digital twin E3 of the food processor E3a can interact with the digital twin E2 of the dishwasher E2a. For example, the digital twin E3 of the food processor can set and update the attributes of the digital twin E5 of the cake on the basis of sensor data; e.g., the detected resistance of the movement of a dough hook can change the viscosity of the dough, which is, e.g., an important property for the dishwasher E2a, e.g., in order to clean the components of the food processor E3a, and for the oven E4, e.g., in order to set the most suitable program for this cake E5a. By placing the cake E5a into the oven E4a, e.g., the digital twin E5 of the cake can now also be linked to the digital twin E4 of the oven E4a according to the “baking process.” Since many further important properties of the dough E5a are known to the oven E4a (such as, e.g., the viscosity), the baking process is, e.g., dynamically optimized and adapted, e.g., with the aid of the AISF or the function DT-F5 according to FIG. 2, which can be provided, e.g., by the 6G network. Finally, at an end of the “baking procedure,” the digital twin E5 of the cake and the communication relationship between at least some of the appliances E2, E3, E4, . . . can be shut down, e.g., via DTRMF or the function DT-F3 and DTLMF or the function DT-F6.

Further aspects and examples according to the disclosure are described below on the basis of an example scenario comprising an oven E4a (FIG. 5) and a dishwasher E2a. After receiving a recipe recommendation, the intelligent oven E4a analyzes the current baking conditions such as the temperature, the humidity, etc., e.g., with the aid of, e.g., 6G-based functions and/or imaging functions. On the basis of this analysis, the oven E4a adapts the baking parameters, e.g., in order to achieve optimum baking results. The intelligent dishwasher E2a, which is, e.g., likewise connected via 6G, monitors, e.g., the use patterns of the appliances and plans the washing cycles in order to optimize energy efficiency. In addition, it receives updates, for example real-time updates, from other appliances (e.g., the oven E4a), e.g., regarding completion of baking procedures, e.g., in order to coordinate the cleaning process efficiently.

Some examples, FIG. 6, relate to the use 300 of the method according to the disclosure and/or of the device 200 according to the disclosure and/or of the system 10 according to the disclosure and/or of the computer-readable storage medium SM according to the disclosure and/or of the computer program PRG according to the disclosure and/or of the data carrier signal DCS according to the disclosure for at least one of the following elements: a) providing 301 a system 10, for example a platform, for an exchange of information of a plurality of digital twins, or b) increasing 302 an efficiency of operation of products, for example appliances, for example household appliances, or c) automating 303 operational sequences of a plurality of products, or d) increasing 304 interoperability of products, for example appliances, for example household appliances, or e) nutrition monitoring 305, for example for personal and/or medical purposes, or f) optimizing 306 energy management of household appliances, for example lowering energy consumption.

1-18. (canceled)

19. A computer-implemented method for digital twins, comprising the following steps:
managing data associated with at least one digital twin of the digital twins;
providing one or more functions for the digital twins; and
providing a wireless communication interface for a data exchange between at least two of the following elements: a) a digital twin, b) a product associated with at least one digital twin of the digital twins, or c) at least one of the functions for the digital twins.

20. The method according to claim 19, wherein the providing of the wireless communication interface includes using a mobile communication system.

21. The method according to claim 19, wherein the managing of the data includes:
executing the at least one digital twin or at least one aspect of the at least one digital twin.

22. The method according to claim 19, wherein the digital twins include at least one of the following elements: a) a digital twin of a product, or b) a digital twin of a person.

23. The method according to claim 19, wherein the providing of the one or more functions includes: providing a function for recognizing and/or identifying objects located in spatial proximity relative to one another.

24. The method according to claim 19, wherein the providing of the one or more functions includes: providing a function for at least one of: (i) protecting an authenticity and/or integrity of the digital twins, or (ii) protecting a communication of the digital twins.

25. The method according to claim 19, wherein the providing of the one or more functions includes: providing a function for resource management for the digital twins.

26. The method according to claim 19, wherein the providing of the one or more functions includes: providing a function for enabling communication relationships between the digital twins.

27. The method according to claim 19, wherein the providing of the one or more functions includes: providing a function for artificial intelligence for supporting data processing associated with the digital twins and/or for supporting an interaction of the digital twins.

28. The method according to claim 19, wherein the providing of the one or more functions includes: providing a function for management of a lifecycle for the digital twins, including at least one of a) instantiation of the digital twins, b) configuration of the digital twins, or c) deactivation of the digital twins.

29. The method according to claim 19, further comprising:
using at least one function of a mobile communication system for providing the one or more functions.

30. The method according to claim 19, further comprising at least one of the following elements:
a) establishing data connections to physical products,
b) ascertaining a position of at least one appliance and/or ascertaining a digital twin associated with the at least one appliance and/or instantiating a digital twin for the at least one appliance,
c) authenticating at least one digital twin,
d) setting up communication relationships between the digital twins,
e) executing at least one digital twin, or
f) deactivating communication relationships between the digital twins.

31. A device for digital twins, the device configured to:
manage data associated with at least one digital twin of the digital twins;
provide one or more functions for the digital twins; and
provide a wireless communication interface for a data exchange between at least two of the following elements: a) a digital twin, b) a product associated with at least one digital twin of the digital twins, or c) at least one of the functions for the digital twins.

32. A system, comprising:
at least one device for digital twins, the at least one device configured to:
manage data associated with at least one digital twin of the digital twins,
provide one or more functions for the digital twins, and
provide a wireless communication interface for a data exchange between at least two of the following elements: a) a digital twin, b) a product associated with at least one digital twin of the digital twins, or c) at least one of the functions for the digital twins; and
at least one product for operation with at least one digital twin.

33. A non-transitory computer-readable storage medium on which are stored commands for processing data associated with digital twins, the commands, when executed by a computer, causing the computer to perform the following steps comprising:
managing data associated with at least one digital twin of the digital twins;
providing one or more functions for the digital twins; and
providing a wireless communication interface for a data exchange between at least two of the following elements: a) a digital twin, b) a product associated with at least one digital twin of the digital twins, or c) at least one of the functions for the digital twins.

34. The method according to claim 19, wherein the method is used for at least one of the following elements: a) providing a system for an exchange of information of the digital twins, b) increasing an efficiency of operation of products, c) automating operational sequences of a plurality of products, d) increasing interoperability of products, e) nutrition monitoring for personal and/or medical purposes, or f) optimizing energy management of household appliances.
